(19) United States
(12) Patent Application Publication
(10) Pub. No.: US 2008/0207003 A1
(43) Pub. Date: Aug. 28, 2008

(54) PRODUCTION METHOD OF SEMICONDUCTOR APPARATUS

(75) Inventor: Toshiyuki HIROTA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/035,240

(22) Filed: Feb. 21, 2008

(30) Foreign Application Priority Data
Feb. 26, 2007 (JP) 2007-045125

(51) Int. Cl. H01L 21/302

(52) U.S. Cl. 438/714; 257/E21.214

(57) ABSTRACT

In order to provide a production method of a semiconductor apparatus that can form a film, even in the case of forming a carbon film, on a semiconductor substrate while maintaining an improved optical transparency at a visible band and while maintaining a preferable adhesion property, the semiconductor apparatus production method includes: a first step of generating and controlling plasma by using oxygen and conducting a plasma operation on a surface of a semiconductor substrate set inside a reaction chamber in which a film is formed on the surface of the semiconductor substrate; and a second step of generating and controlling plasma by using hydrogen and conducting a plasma operation on the surface of the semiconductor substrate set inside the reaction chamber, wherein the second step is conducted after the first step and before forming the film on the surface of the semiconductor substrate inside the reaction chamber.

### BACKGROUND OF THE INVENTION

1. Field of the Invention

The present invention relates to a production method of a semiconductor apparatus, and in particular, the present invention relates to a production method of a semiconductor apparatus for forming a hard mask on a semiconductor substrate.

Priority is claimed on Japanese Patent Application No. 2007-45125, filed Feb. 26, 2007, the content of which is incorporated herein by reference.

2. Description of the Related Art

In a conventional production step of a semiconductor apparatus such as DRAM (dynamic random access memory), in order to form a pattern like a through-hole on a foundation layer such as an interlayer dielectric, a patterning operation is conducted on a photoresist layer which is obtained by forming a photoresist on the foundation layer, and an etching operation is conducted by using the photoresist layer as a mask of the foundation layer.

In recent years, semiconductor apparatuses have become smaller, and therefore, there has been a necessity of forming very fine patterns. In order to improve a resolution of the patterns, from a point of view of a depth of focus upon being exposed, it is necessary to reduce a thickness of the photoresist layer.

However, if a thickness of the photoresist layer is reduced, durability of the photoresist layer for conducting an etching operation is reduced, that is, there is a case in which the photoresist layer cannot be used as a mask. Therefore, there is a generally known method of forming a hard mask in place to an etching by using the photoresist mask.

A hard mask is a mask which has a high etching selectivity to the foundation layer and which is provided between the photoresist layer and the foundation layer. Patterns of the photoresist mask are temporally copied to the hard mask, and after this, a patterning operation is conducted on the foundation layer by using the hard mask as a mask.

Silicon oxide, silicone nitride and the like which have a large etching selectivity to the foundation layer have been generally used as materials of the hard mask. However, if the foundation layer includes a silicon oxide film, a silicon nitride film, or the like, it is not possible to obtain sufficient etching selectivity.

Therefore, in recent years, in order to obtain a hard mask which can provide sufficient etching selectivity to such films, amorphous carbon to which an ashing operation can be conducted has been used as a hard mask. However, by using the hard mask made from amorphous carbon, it is difficult to obtain appropriate etching selectivity to the photoresist film which is mainly made from carbon.

With regard to such a problem, a solution is generally known in which an intermediate layer between the hard mask and the photoresist film is provided, patterns of the photoresist mask are temporally copied to the intermediate layer, and after this, patterns are copied to the hard mask. In Japanese Patent Application, First Publication No. 2005-45053, a solution is disclosed in which Si-containing amorphous carbon is used as the hard mask in place of simple amorphous carbon.

In order to form such a film, in general, a parallel plate-type PE-CVD (Plasma-enhanced chemical vapour deposition) apparatus is used. Hydro-carbon gas such as methane (CH₄), acetylene (C₂H₂), ethane (C₂H₆), propylene (C₃H₆), ethylene (C₂H₄), and the like are used as a reaction gas. Inert gases such as helium (He), argon (Ar), and the like are used as the carrier gas.

In general, the parallel plate-type PE-CVD apparatus has a reaction chamber which is covered with a chamber and is blocked out from the outside. The reaction chamber has a stage on which the semiconductor substrate is mounted and heated, and a film is formed while the semiconductor substrate is mounted on the stage and a temperature of the semiconductor substrate is maintained at a comparatively high temperature (500-550° C.).

However, an amorphous carbon film (hereinafter, carbon film) formed at 550° C. has a high optical absorption coefficient at a band of visible light. Moreover, if the film is formed so as to be thicker, there is a problem in which it is not usable because it is difficult to recognize and adjust positions of marks set on another side of the substrate due to the foundation layer.

In accordance with researches by inventors of the present invention, if a temperature of a heater is lowered to approximately 300-400° C., it was recognized that it was possible to reduce an absorption coefficient k to 0.1 or lower at a visible light band. Moreover, a problem was recognized in which if the temperature was 400° C. or lower upon forming the film, an adhesion property is deteriorated between a carbon film and a film (mainly an oxide film or a nitride film) which is to be processed or changed.

The inventors have recognized that the following two points mainly cause deterioration of the adhesion property. That is, the points are contamination by organic matter on a surface of the oxide film from the environment, and low adhesion property which is originally provided between the Si—OH bond on the surface and the carbon film.

As a result of researches by the inventors of the present invention, it was recognized that it was possible to have comparatively good adhesion property if the carbon film was formed immediately after washing the semiconductor substrate by using aqueous hydrogen peroxide sulfate. However, a tendency was observed that the adhesion property was deteriorated along with time after washing. Such adhesive properties were evaluated in accordance with a table test and modified Edge Liftoff Test (mELT method).

Furthermore, when the inventors of the present invention researched in detail, it was recognized that the adhesion property was dependent on time after washing, and there was a possibility of influence of contamination from something. Therefore, by using TDS-GOMS (thermal desorption gas chromatography, the inventors researched the contamination caused by organic matter in the case of leaving the semiconductor substrate in a generally used clean room environment after washing.

As a result of researching, it was detected that a ratio of molecules which have a comparatively large molecular weight increases along with time of leaving. Based on analysis results, it was possible to make an assumption in which the molecules were mainly DOP (dioctyl phthalate), DBP (dibutyl phthalate) and DOA (dioctyl adipate). Such molecules are generally used as a plasticizer applied to a resin, and it is assumed that such molecules were spread from apparatuses, a building, and the like.

As described above, it was recognized that there was a relationship between the amount of organic matter and an adhesive property. Therefore, it is possible to assume that one source of deterioration of the adhesion property is contamination by organic matter on a surface of the semiconductor substrate. In accordance with such an assumption, there was a proposal for solving the problem, namely, a strict control of the waiting time from a washing step to a carbon film forming step. However, it was not possible to maintain the waiting time because of various operating conditions and situations of the apparatus and complex control, and moreover, the results were not stable.

In accordance with the above-described researches, the inventors of the present invention conceived an idea, that is, it is important to remove the above-described organic matter after leading the semiconductor substrate into a reaction chamber of the PE-CVD apparatus for forming the carbon film and before forming the carbon layer on a surface of the semiconductor substrate.

The present invention was conceived to solve the above-described problems. The present invention has an objective to provide a production method of a semiconductor apparatus that can form a film on a semiconductor substrate while maintaining an improved optical transparency at a visible band and while maintaining a preferable adhesion property, and moreover, that can maintain both a preferable adhesion property and an improved optical transparency even in the case of forming a carbon film.

### SUMMARY OF THE INVENTION

In order to solve the above-described problems the present invention provides, for example, the following solutions.

A first solution is a semiconductor apparatus production method including: a first step of generating and controlling plasma by using oxygen and conducting a plasma operation on a surface of a semiconductor substrate set inside a reaction chamber in which a film is formed on the surface of the semiconductor substrate; and a second step of generating and controlling plasma by using a hydrogen and conducting plasma operation on the surface of the semiconductor substrate set inside the reaction chamber, wherein the second step is conducted after the first step and before forming the film on the surface of the semiconductor substrate inside the reaction chamber.

A second solution is the above-described semiconductor apparatus production method, wherein the film includes carbon.

A third solution is the above-described semiconductor apparatus production method, wherein the surface is a foundation layer including a silicon oxide film or a silicon nitride film.

A fourth solution is the above-described semiconductor apparatus production method, wherein the film is formed while heating at 300-400° C.

A fifth solution is the above-described semiconductor apparatus production method, wherein inert gas is used in addition to oxygen as a carrier gas in the first step.

A sixth solution is the above-described semiconductor apparatus production method, wherein a ratio of oxygen is 5-20% is in the first step.

A seventh solution is the above-described semiconductor apparatus production method, wherein inert gas is used in addition to hydrogen as a carrier gas in the second step.

An eighth solution is the above-described semiconductor apparatus production method, wherein a ratio of hydrogen is 5-20% is in the second step.

As described above, the first solution includes a first step of generating and controlling plasma by using oxygen and conducting a plasma operation on a surface of a semiconductor substrate set inside a reaction chamber in which a film is formed on the surface of the semiconductor substrate, and the first step is conducted before forming the film on the surface of the semiconductor substrate. Therefore, without putting the semiconductor substrate outside after being lead into the reaction chamber, the organic matter adhering on the surface is oxidized and removed as carbon dioxide (CO₂) gas or carbon monoxide (CO) gas by using plasma of highly activated oxygen molecules with large power. After this, the film can be formed without putting the semiconductor substrate out of the reaction chamber, that is, it is possible to form the film on the surface while maintaining effects of the first step.

After conducting the first step, while the semiconductor substrate is left in the reaction chamber, the second step is conducted in which a plasma operation is conducted on the surface by generating and controlling plasma that is generated by using oxygen.

Therefore, without putting the semiconductor substrate outside after leading the semiconductor substrate into the reaction chamber, in accordance with the same theory as the first step, the organic matter adhering on the surface is oxidized slower than the first step and is removed with small power caused by using plasma of less activated hydrogen molecules than oxygen. After this, the film can be formed without putting the semiconductor substrate out of the reaction chamber, that is, it is possible to form the film on the surface while maintaining effects of the second step.

By using the first solution including both the first and second steps conducted in an ascending order, it is possible to gradually control the power of the plasma by changing the gas used for generating plasma without changing conditions such as a voltage. Therefore, it is possible to form the film without harming the surface of the semiconductor substrate because of too strong a power and without leaving the organic matter on the surface of the semiconductor substrate because of too small a power, and it is possible to prevent the products from being wasted due to the film peeling.

As described in the second solution, due to carbon which is included in the film, even when the surface on which the film is formed is a foundation layer including a silicon oxide film or a silicon nitride film, it is possible to obtain a necessary etching selectivity, and it is possible to improve an adhesion property between a thin film including carbon and the semiconductor substrate.

As described in the third solution, due to the surface on which the film is formed being the foundation layer including a silicon oxide film or a silicon nitride film, it is possible to improve an adhesion property between the film and the semiconductor substrate made from silicon, and it is possible to obtain a necessary etching selectivity regarding the film.

As described in the fourth solution, due to the film which is formed while heating the semiconductor substrate at a temperature in a range of 300-400° C., molecular bond similar to graphite is reduced. Therefore, it is possible to improve optical transparency at a visible band, and it is possible to recognize and adjust marks on another side of the substrate.

As described in the fifth solution, due to inert gas which is used as the carrier gas in addition to the above-described oxygen gas, it is possible to soften or reduce activity of the plasma when the plasma is generated, and it is possible to improve safety of the plasma operation of the first step.

As described in the sixth solution, due to the oxygen gas of 5-20%, it is possible to effectively remove the organic matter on the surface of the semiconductor substrate, and it is possible to stably generate plasma.

As described in the seventh solution, due to inert gas used as the carrier gas in addition to the hydrogen gas, it is possible to soften or reduce activity of the plasma when the plasma is generated, and it is possible to improve safety of the plasma operation of the second step.

As described in the eighth solution, due to the hydrogen gas of 5-20%, it is possible to obtain the surface of the semiconductor substrate which is effectively hydrogen-terminated, and it is possible to stably generate plasma.

### BRIEF DESCRIPTION OF THE DRAWINGS

FIG. 1 is a drawing which shows a cross-section obtained by cutting a PE-CVD (Plasma-enhanced chemical vapour deposition) apparatus of one embodiment in a vertical direction.

### DETAILED DESCRIPTION OF THE INVENTION

One embodiment is explained below in reference to the drawings.

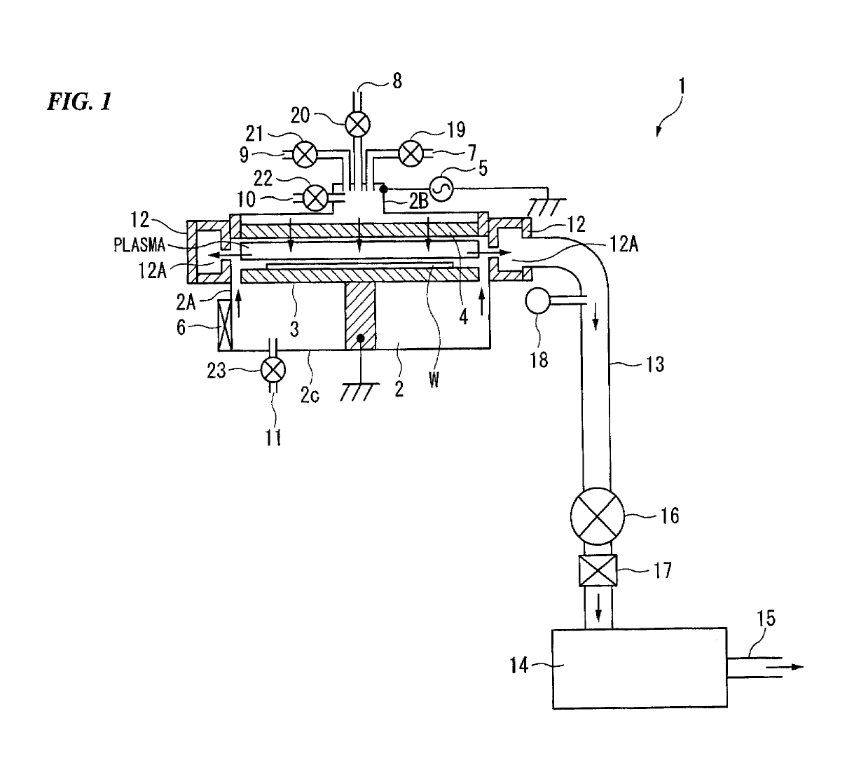

A production method of a semiconductor apparatus of this embodiment uses a parallel plate-type PE-CVD (Plasma-enhanced chemical vapour deposition) apparatus shown in FIG. 1 and is conducted inside a reaction chamber 2 which is blocked out from the outside by a wall 2A.

The reaction chamber 2 includes: a stage 3 on which a semiconductor substrate W can be mounted and which is an anode terminal provided at a center of the reaction chamber 2; and a shower plate 4 which is a cathode terminal provided above the stage 3 and which leads gas onto the stage 3. An RF power source 5 which generates RF (radio frequency) voltage between the terminals is provided outside the reaction chamber 2 together with both a blocking capacitor (not shown in drawings) and an impedance matching box (not shown in drawings) which are provided between the reaction chamber 2 and the RF power source 5.

A slit valve 6 is provided at a side of the reaction chamber 2 for controlling transportation of the semiconductor substrate W inserted and taken out of the reaction chamber 2. The parallel plate-type PE-CVD apparatus 1 includes: a first gas line 7 which is provided at an upper portion 2B of the reaction chamber 2 and which leads a first gas via the shower plate 4 from the upside of the reaction chamber 2; a second gas line 8 which is provided at an upper portion 2B of the reaction chamber 2 and which leads a second gas via the shower plate 4 from the upside of the reaction chamber 2; a third gas line 9 which is provided at an upper portion 2B of the reaction chamber 2 and which leads a third gas via the shower plate 4 from the upside of the reaction chamber 2; and a fourth gas line 10 which is provided at an upper portion 2B of the reaction chamber 2 and which leads a fourth gas via the shower plate 4 from the upside of the reaction chamber 2. Moreover, the parallel plate-type PE-CVD apparatus 1 includes a fifth gas line 11 at a bottom portion 2C of the reaction chamber 2. The parallel plate-type PE-CVD apparatus 1 has a gas discharging duct (gas discharging apparatus) 12 including a gas discharging chamber 12A, and inside of the gas discharging chamber 12A is empty. Therefore, as shown in FIG. 1, a cross-section of the gas discharging duct 12 is in a square shape. However, if the gas discharging duct 12 is shown from directly above, the gas discharging duct has a donut shape. That is, the gas discharging duct 12 is provided so as to surround outside of the reaction chamber 2.

The gas discharging duct 12 is connected to a gas discharging pump 14 via a gas discharging pipe 13, and the gas discharging pump 14 has a gas-discharging-pump-gas-discharging-port 15. The gas discharging pipe 13 includes: a main gas discharging valve 16 controlling discharging operation of gas; a pressure control valve 17 controlling pressure inside the gas discharging pipe 13; and a pressure sensor 18 measuring pressure inside the gas discharging pipe 13. The gas to be discharged from the reaction chamber 2 is uniformly discharged to the gas discharging duct 12, and after this, the gas is discharged via the gas discharging pipe 13, gas discharging pump 14 and the gas-discharging-pump-gas-discharging-port 15.

Moreover, a valve 19 is provided at the first gas line 7, a valve 20 is provided at the second gas line 8, a valve 21 is provided at the third gas line 9, a valve 22 is provided at the fourth gas line 10, and a valve 23 is provided at the fifth gas line 11. Therefore, it is possible to independently control the amount of gas led from each of the gas lines.

First, the semiconductor substrate W is brought into the reaction chamber 2 via the slit valve 6 and is set on the stage 3. The stage 3 has a heater inside, and a temperature of the heater is preferably set to 300-400° C. in order to obtain clarity of the semiconductor substrate W after forming the film so as to have an absorption coefficient of k<0.1 at a range of visible light of 633 nm.

In accordance with the fact that a carbon film indicates both electrical conductivity after heating the film at 500° C. or higher and insulation after forming the film at 300-400° C., it is assumed that there is a relationship between absorption of visible light and characteristics of the film similar to graphite. Moreover, it is assumed that it is possible to obtain a clear film because molecular bond similar to graphite is reduced by heating at a low temperature.

After putting the semiconductor substrate W on the stage 3, the stage 3 is set to a predetermined height, and a temperature of the semiconductor substrate 3 is stabilized.

Next, the first and fifth gas is a carrier gas, and inert gas, that is the carrier gas, is supplied through the first gas line 7 and the fifth gas line 11. The second gas is oxygen gas (O₂) used for generating plasma in a first step and is supplied via the second gas line 8 at the same time when the carrier gas is supplied, and a pressure inside the reaction chamber 2 is controlled so as to be a predetermined pressure (for example, at 655 Pa (5 Torr)).

It is possible to apply any inert gas as the carrier gas. However, helium (He) is preferable.

It is possible to apply 5 l/m to a rate of flow of the carrier gas, and 0.5 l/m to O₂ (if O₂ is 0.5 l/m, ratio of O₂ is 9% and it is in a more preferable range).

A range of O₂ is preferably 5-20%, and more preferably, 9-17%.

The above-described range is a range in which it is possible to sufficiently remove the organic matter on a surface of the semiconductor substrate, and in which it is possible to stably generate plasma.

After the above-described operation, RF voltage is applied between the stage 3 and the shower plate 4 by using the RF power source 5, and generates plasma by a power of, for example, 800 W in order to conduct a plasma operation on a surface of the semiconductor substrate W for, for example, 10 seconds. For example, in the case of an operation apparatus of a 300 mm wafer, power for generating plasma is preferably in a range of 400-1000 W.

Therefore, it is possible to oxidize the organic matter adhering on a surface of the semiconductor substrate W to which the plasma operation is conducted, and it is possible to remove the organic matter which becomes carbon dioxide (CO₂) gas or carbon monoxide (CO) gas.

After the above-described operation, application of the RF voltage is stopped, and supply of O₂ gas is stopped.

Next, the third gas is hydrogen gas (H₂) used for generating plasma in a second step and is supplied via the third gas line 9 at the same time when the carrier gas is supplied, and a pressure inside the reaction chamber 2 is controlled so as to be a predetermined pressure (for example, at 532 Pa (4 Torr)).

It is possible to apply any inert gas as the carrier gas. However, the same as the first step, helium (He) is preferable.

It is possible to apply 5 l/m to a rate of flow of the carrier gas, and 0.5 l/m to H₂.

A range of H₂ is preferably 5-20%, and more preferably, 9-17%.

After the above-described operation, RF voltage is applied between the stage 3 and the shower plate 4 by using the RF power source 5, and generates plasma by a power of, for example, 800 W in order to conduct a plasma operation on a surface of the semiconductor substrate W for, for example, 10 seconds. For example, power for generating plasma is preferably in a range of 200-400 W.

If the second step is not conducted and a film is formed soon after the first step on a surface on which the first step is conducted of the semiconductor substrate W, it is possible to obtain stable results and to improve the adhesion property compared to the case of omitting the first step. However, it is not sufficient.

Moreover, if the second step is conducted without conducting the first step, it is possible to remove the organic matter to some degree on a surface on which the second step is conducted of the semiconductor substrate. However, it is more preferable to conduct both the first step and the second step because it is possible to obtain the surface on which both steps are conducted and which has better adhesion property with regard to a film formed in a following film forming step.

After the above-described operation, application of the RF voltage is stopped, and supply of H₂ gas is stopped.

While conducting the first step and the second step, the gas discharged from the reaction chamber 2 is uniformly discharged via the gas discharging duct 12 arranged so as to surround the stage 3 (in a donut shape). Moreover, via the gas discharging pipe 13 to which the main gas discharging valve 16, the pressure control valve 17 and the gas discharging pump 14 are connected, the gas is discharged out of the gas-discharging-pump-gas-discharging-port 15 of the gas discharging pump 14.

In accordance with the above-described steps, it is possible to conduct operations while changing the atmosphere inside the reaction chamber 2 at each of the steps.

At last, the fourth gas is a source gas used for forming the film and is supplied via the fourth gas line 10 at the same time when the carrier gas is supplied. Gas of hydrocarbon series is used for forming the carbon film. The gas is supplied on the semiconductor substrate W via the shower plate 4.

Here, it is possible to apply any inert gas to the carrier gas, and mixed gas of argon (Ar) and helium (He) is preferable. For example, it is possible to mix 6.5 l/m (6.5 SLM) of Ar and 0.5 l/m (0.5 SLM) of He. It is preferable to use propylene (C₃H₆), acetylene (C₂H₂) as the source gas, and the like, and for example, it is possible to supply the source gas at 600 seem.

After stabilizing the temperature, setting the gas flow ratio at a predetermined value and setting a pressure at a predetermined value (for example, 665 Pa (5 Torr)), that is, when conditions and preparations for forming the film are ready, the RF voltage is applied between the stage 3 and the shower plate 4 in order to generate plasma at a power of, for example, 1100 W. By applying plasma, molecules of the source gas of hydrocarbon series are polymerized, and a carbon film is formed on a surface on which plasma is applied on the semiconductor substrate W. It is possible to obtain a clear film with a low absorption coefficient at a visible band while maintaining absorption property between the semiconductor substrate W and the carbon film. Therefore, it is possible to prevent the products from being wasted due to the film peeling.

In accordance with the above-described steps, it is possible to produce a semiconductor apparatus with a carbon film on the semiconductor substrate W which has an improved optical transparency at a visible band while maintaining a preferable adhesion property between the semiconductor substrate W and the carbon film.

### EXAMPLE

As described below, a sample of a carbon film was formed by using a parallel plate-type PE-CVD apparatus 1 shown in FIG. 1.

First, the semiconductor substrate W on which a film would be formed was led into the reaction chamber 2 via the slit valve 6 and was set on the stage 3, and a temperature of the heater of the stage 3 was set to 350° C.

After putting the semiconductor substrate W on the stage 3, the stage 3 was set to a predetermined height, and a temperature of the semiconductor substrate 3 was stabilized.

Next, the carrier gas which was He and 5 l/m (5 SLM) was supplied into the reaction chamber 2 via both the first gas line 7 and the fifth gas line 11, 11/m (1 SLM) of O₂ was supplied via the second gas line 8 into the reaction chamber 2, and a pressure inside the reaction chamber was set to 665 Pa (5 Torr).

After the above-described operation, RF voltage was applied between the stage 3 and the shower plate 4 by using the RF power source 5, and generated plasma by a power of, for example, 800 W in order to conduct a plasma operation on a surface of the semiconductor substrate W for, for example, 10 seconds.

After the above-described operation, application of the RF voltage was stopped, and supply of O₂ gas was stopped.

Next, the carrier gas which was He and 5 l/m (SSLM) was supplied into the reaction chamber 2 via both the first gas line 7 and the fifth gas line 11, 1 l/m (1 SLM) of H was supplied via the third gas line 13 into the reaction chamber 2, and a pressure inside the reaction chamber was set to 532 Pa (4 Torr)

After the above-described operation, RF voltage was applied between the stage 3 and the shower plate 4 by using the RF power source 5, and generated plasma by a power of, for example, 800 W in order to conduct a plasma operation on a surface of the semiconductor substrate W for, for example, 10 seconds. After the above-described operation, application of the RF voltage was stopped, and supply of H₂ gas was stopped.

Next, the carrier gas which was a mixed gas of both 6.5 l/m (6.5 SLM) of Ar and 0.5 l/m (0.5 SLM) of He was supplied into the reaction chamber 2 via both the first gas line 7 and the fifth gas line 11, and at the same time, 600 sccm of C₃ H₆ which was the source gas was supplied via the fourth gas line 10 into the reaction chamber 2. Both the carrier gas and the source gas were supplied onto the semiconductor substrate W via the shower plate 4, and a pressure inside the reaction chamber was set to 665 Pa (5 Torr).

After stabilizing the temperature, setting a gas flow ratio at a predetermined value and setting a pressure at a predetermined value, that is, when conditions and preparations for forming the film were ready, the RF voltage was applied between the stage 3 and the shower plate 4 by using the RF power source 5 in order to generate plasma at a power of 1100 W. By applying plasma, molecules of C₃ H₆ were polymerized, and a carbon film was formed on a surface on which plasma is applied of the semiconductor substrate W.

A surface of the sample on which the above-described operation was conducted was inspected by using a multiple reflection type FT-IR (Fourier transform infrared spectroscopy), and obtained a result indicating an increase of Si—H bonds. With regard to such a result, there is a possibility in which the carbon film has higher adhesion property to Si—H bonds compared to a Si—OH bond which has a strong polarity.

What is claimed is:

1. A semiconductor apparatus production method comprising:
a first step of generating and controlling plasma by using oxygen and conducting a plasma operation on a surface of a semiconductor substrate set inside a reaction chamber in which a film is formed on the surface of the semiconductor substrate; and
a second step of generating and controlling plasma by using hydrogen and conducting a plasma operation on the surface of the semiconductor substrate set inside the reaction chamber, wherein
the second step is conducted after the first step and before forming the film on the surface of the semiconductor substrate inside the reaction chamber.

2. A semiconductor apparatus production method according to claim 1, wherein the film includes carbon.

3. A semiconductor apparatus production method according to claim 1, wherein the surface is a foundation layer including a silicon oxide film or a silicon nitride film.

4. A semiconductor apparatus production method according to claim 1, wherein the film is formed while heating at 300-400° C.

5. A semiconductor apparatus production method according to claim 1, wherein inert gas is used in addition to oxygen as a carrier gas in the first step.

6. A semiconductor apparatus production method according to claim 1, wherein a ratio of oxygen is 5-20% is in the first step.

7. A semiconductor apparatus production method according to claim 1, wherein inert gas is used in addition to hydrogen as a carrier gas in the second step.

8. A semiconductor apparatus production method according to claim 1, wherein a ratio of hydrogen is 5-20% is in the second step.
